(19) United States
(12) Patent Application Publication
(10) Pub. No.: US 2016/0111847 A1
(43) Pub. Date: Apr. 21, 2016

(54) High average power integrated optical waveguide laser

(71) Applicant: Applied Physical Electronics L.C., Austin, TX (US)

(72) Inventor: William C. Nunnally, Austin, TX (US)

(73) Assignee: APPLIED PHYSICAL ELECTRONICS, L.C., Austin, TX (US)

(21) Appl. No.: 14/852,553

(22) Filed: Sep. 12, 2015

Related U.S. Application Data
(63) Continuation of application No. PCT/US2014/023931, filed on Mar. 12, 2014.
(60) Provisional application No. 61/778,064, filed on Mar. 12, 2013.

(51) Int. Cl. H01S 3/063; H01S 3/094; H01S 3/042; H01S 3/04; H01S 3/067; H01S 3/10; H01S 3/0941; H01S 5/40

(52) U.S. Cl. CPC H01S 3/0637; H01S 3/0941; H01S 3/094049; H01S 5/4025; H01S 3/0405; H01S 3/06704; H01S 3/10053; H01S 3/042

(57) ABSTRACT

A high power laser whose output is a matrix of individual phase controlled pixels is disclosed, each pixel containing a number of low power, single transverse mode, phase coherent gain channel outputs. Each row of pixels is formed as an optical pump waveguide that is transverse or orthogonal to a number of parallel, longitudinal gain channels integrated within or adjacent to the transverse pump waveguide. Optical pump energy is produced and injected by a number of parallel laser diode bars, located along both longitudinal sides of the pump waveguide. Waste thermal energy from the pump diodes and gain channels is extracted from each laser row by integrating the row pump waveguide, gain channels, and pump diodes within a heat exchanger.

This application is a continuation of International Application No. PCT/US2014/023931, titled “High Average Power Integrated Optical Waveguide Laser,” filed on Mar. 12, 2014, which claims the benefit of U.S. Provisional Application No. 61/778,064, titled “High Average Power Integrated Optical Waveguide Laser,” filed on Mar. 12, 2013. The aforementioned applications are hereby incorporated herein by reference in their entirety and for all purposes.

### FIELD OF THE INVENTION

The present disclosure relates in general to high power continuous wave and pulsed lasers.

### BRIEF DESCRIPTION OF THE DRAWINGS

The benefits, features, and advantages of the present disclosure will become better understood with regard to the following description, and accompanying drawings.

FIG. 1 is a top perspective view of a basic transverse pump waveguide—gain channel system.

FIG. 2 is a transverse pump waveguide in cross section view of a system.

FIG. 3 is a pixel input configuration view of a system.

FIG. 4 depicts an adjacent gain channel coherence facilitation of a system.

FIG. 5 depicts a gain channel output option of a system.

FIG. 6 depicts a frequency locked electrically controlled pump diode bar assembly.

FIG. 7 is a cross section view of a waveguide fabrication.

FIG. 8 depicts a row heat exchanger in cross section view.

FIG. 9 depicts a matrix row electrical and thermal assembly of a system.

FIG. 10 depicts a matrix laser output of a system.

FIG. 11 depicts a matrix laser phase conjugation of a system.

FIG. 12 depicts a multiple laser installation.

### DETAILED DESCRIPTION

High power continuous and pulsed lasers are required for many applications, such as but not limited to material processing, welding, and cutting. There are a number of problems with existing laser systems that are being scaled to power levels of 100's of kilowatts and even over 1 megawatt.

One problem with these existing laser systems is their excessive size, due to inefficient employment of volume which limits mobility. The maximum optical materials power density for many materials is in excess of 1 GW/cm². Even if the average power 1 density is set at 10 MW/cm², the total active lasing media cross section required for a 1 MW laser would be only 0.1 cm².

Another problem with existing laser systems is that they require collecting and applying pump energy from a large number of pump sources. This calls for a pump combiner that efficiently produces, collects, transports and applies pump energy in a compact geometry.

Yet another problem is excessive parts count and complexity, which limits reliability and increases initial cost and maintenance costs. What is needed is an integrated configuration that can be mass produced at reasonable cost.

Still another problem is that multiple lasers must be operated in parallel to obtain total output power, which requires phase synchronization among outputs. This is difficult when lasers are spatially distant, since such a system requires phase coherence between many parallel sources.

Still another problem is extreme heat removal requirements due to overall efficiencies of about 25% and conventional thermal management approaches, which need low thermal resistance and sufficient heat transfer surface area

Still another problem is non-linear losses in the gain medium due to operation at high optical power densities, which reduces efficiency and leads to large mode area fibers. Such systems need an operating configuration that operates at low power density and single mode structure.

Still another problem is poor beam quality due to multi-mode configurations, which limits coherent adding and long distance propagation. A single transverse mode is desired to obtain a diffraction limited beam. 1. Slab Lasers—Slab lasers in which a thick slab of gain media is pumped with optical energy, either flash lamps or injection laser diode arrays

Several different technologies have been employed in the development of high power lasers. One such technology is slab lasers. Slab lasers can be operated in an oscillator mode or master oscillator power amplifier mode. The slab laser is limited by the removal of thermal energy from the slab. Slab lasers are efficient and rugged, but the crystal or ceramic slabs used as gain media have low thermal conductivity. The conversion efficiency of a slab laser is on the order of 50%, which means that the waste thermal energy that must be removed is approximately equal to the laser energy. The waste energy resident in the slab results in expansion, which affects the laser cavity such that the laser can be operated in an adiabatic mode. In addition, the output beam of a slab laser is naturally in a multi-transverse and longitudinal mode due to the dimensions of the slab and the optical cavity. Thus special optics are required to generate single transverse mode outputs necessary for good beam quality and long distance propagation. The optics employed to provide single transverse mode outputs do not efficiently use the volume of the gain media and thus reduce the overall efficiency. The average optical power density in a slab laser is low because the gain volume is not used efficiently. For example, the optical power damage threshold is on the order of 1 GW/cm². Thus only 0.1 cm² of gain material is required, but much larger volumes and thus much lower power densities are employed in state of the art slab lasers. It is important to note that non-linear effects like self-phase modulation, stimulated Raman scattering (SRS), and stimulated Brillouin scattering (SBS) also limit the power density that can be employed in a slab laser. In summary, slab lasers are hardware intensive, requiring many optical components and thermal components to operate the system which is further limited by thermal energy removal and obtaining the proper output mode structure for application.

Another laser technology is fiber lasers. A fiber laser is configured such that the core of the optical fiber is the gain medium and the cladding is used to apply the pump energy to the core all along the fiber. In a fiber laser, all the pump energy must be injected into the cladding at the input to the fiber and at the output of the fiber. The optical pump energy for a fiber laser is collected using a large number of optical elements from injection laser diodes, injected into transport fibers, and then coupled into the ends of the gain fiber. This complex system has progressed to provide very high power from a single fiber because of the difficulty of collecting and coupling the pump energy into the gain fiber. The requirement that all of the pump energy be injected at the ends of the gain fiber requires that the coupling system, which must concentrate the pump energy into a small area, is extremely difficult to design and build. Furthermore, the coupling system must be extremely efficient and handle extremely high powers.

Disk lasers are embodied in thin semiconductor or ceramic gain material disks that are pumped with optical energy. The disks are mounted on good heat sinks to extract the thermal energy from one side and illuminated with pump energy on the output side. Optical pump energy is focused on the disk to determine the size and transverse mode parameters of the output beam. Multiple disk assemblies are optically connected in series to provide an amplifier. The removal of thermal energy from the disk is the factor limiting the output power of each disk.

Electric or optically pumped gas or alkali vapor lasers employ either electrical discharge or optical energy as a pump source. The energy density produced by the pumping method is determined by the absorption characteristics of the gas and the gas density. Conventional gas lasers have relatively low energy density and thus are relatively large. The size is further increased by the size, volume, and rate of the required gas/vapor flow which requires large hardware and cooling systems. In some cases, the gas/vapor are very toxic to man and materials.

Chemical lasers employ exothermic reactions to provide the pump energy for the lasing medium. The advantage of chemical lasers is that the minimum electrical and optical pump energy is required. In the past, this type of laser was favored due to the electrical and optical power available. This type of laser employs materials that are toxic and must be cooled and recycled in order to avoid deleterious environmental and human hazards.

In reviewing each of these types of laser systems, shortcomings of each system become apparent. A major limitation of high power slab lasers is the removal of thermal energy from the optically pumped slabs of doped ceramic lasing mediums because of the very long thermal time constant. This limitation is addressed by employing very thin slabs and employing multi-pass beam paths to extract the gain energy or employing multiple slabs that are mechanically multiplexed to allow the slabs to cool. A second limitation of slab lasers is the formation of a high quality beam which requires a large number of optical components. Thus slab lasers require excessive hardware, which results in large initial cost as well as costly maintenance and alignment expense.

A major problem with very high power fiber lasers is related to cooling all the laser components, including the pump laser diodes, the collection optics, the transport optics, the coupling optics, and the gain fiber itself. Another limitation of high power fiber lasers is the requirement to operate each gain fiber at very high power density. This requirement is manifested through employing special cross section fibers or large mode area fibers in order to provide the volume of gain media necessary to operate at high power. However, employing a large diameter core allows off axis modes to absorb pump energy and to participate in the lasing process. Thus, in applications in which beam quality is important and a single transverse mode output is desired, it is necessary to prevent the off axis modes from propagating along the fiber. The gain of the off axis modes is reduced by coiling the gain fiber at a specific radius so that the off axis modes lose energy and the central, transverse on axis mode becomes dominant. Another limitation of fibers lasers is the non-linear power losses due to the high power at which the lasers are operated. The non-linear losses include Stimulated Brillouin Scattering (SBS), Stimulated Raman Scattering (SRS), and Self Phase Modulation (SPM), all of which result in energy loss from the desired output beam.

Optically pumped disk lasers, in which a thin solid state or ceramic gain media is pumped with optical energy, provide near single longitudinal mode outputs. The transverse size of the output beam is dependent upon the size of the spot illuminated by the pump energy. A major limitation of high power disk lasers is the requirement for complicated optical pump and output beam optics as well as thermal cooling systems. Thus disk lasers are hardware excessive that results in a large initial cost as well as costly maintenance, and alignment complexity and expense.

It may be seen that each of these existing systems exhibit important shortcomings for high power applications. A laser system that overcomes these shortcomings is thus highly desirable.

In various implementations, a high power laser has an output that is a matrix of individual phase controlled “pixels,” each pixel containing a number of low power, single transverse mode, phase coherent gain channel outputs. Each row of pixels is formed as an optical pump waveguide that is transverse or orthogonal to a number of parallel, longitudinal gain channels integrated within or adjacent to the transverse pump waveguide. Optical pump energy is produced and injected by a number of parallel, laser diode bars.

In various implementations, the systems and techniques described herein support the construction of a laser that is compact and portable.

In various implementations, the systems and techniques described herein support the elimination of complicated pump energy collection optics, transfer fibers, and coupling optics as used in parallel optical fiber lasers.

In various implementations, the systems and techniques described herein support the control of all laser parameters through design and fabrication methods.

In various implementations, the systems and techniques described herein support modifying and tuning each laser operation during the fabrication process using ion implantation or UV laser methods.

In various implementations, the systems and techniques described herein support the design and fabrication of a laser using photo-lithographic tools and techniques that may reduce cost.

In various implementations, the systems and techniques described herein support the generation of high power single transverse mode output beams without high power losses due to non-linear optical effects.

In various implementations, the systems and techniques described herein support the generation of a pixelated output matrix of beams with pixel phase control which eliminated deformable mirrors commonly used for phase conjugation.

In various implementations, the systems and techniques described herein support temperature control through integration of the laser pump waveguide and gain channels into the heat exchanger.

In various implementations, the systems and techniques described herein support a reduction in the part count and thus maintainability of a laser system when compared to multiple fiber lasers.

In various implementations, the systems and techniques described herein support phase coherence across a number of adjacent waveguide gain channels.

In various implementations, the systems and techniques described herein support laser line width control of integrated gain channel output wavelength.

In various implementations, the systems and techniques described herein support wavelength sensitive heating of gain channels absorbent materials during fabrication in order to reduce waveguide losses due to waveguide interface imperfections and gain channel material defect scattering.

In various implementations, the systems and techniques described herein support a single power supply to be used by more than one laser, one at a time, which facilitates multiple lasers per site.

It should be understood that the invention is not limited to the particular embodiments described, and that the terms used in describing the particular embodiments are for the purpose of describing those particular embodiments only, and are not intended to be limiting, since the scope of the present invention will be limited only by the claims.

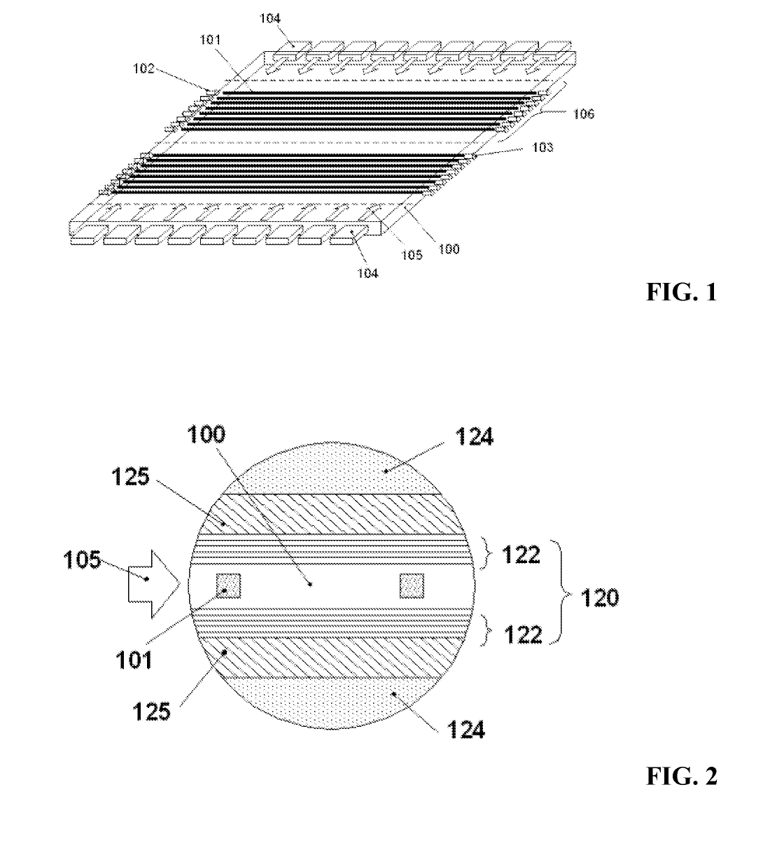

FIG. 1 illustrates one implementation of a Transverse Pump Matrix Wave Guide Laser (TPMWGL), with a transverse pump waveguide center (100), in which or adjacent to, are integrated a number of longitudinal gain channels (101), the pump energy being applied in an orthogonal direction (105) to the absorbing gain channels. The pump energy is injected into the pump waveguide core along each side of the pump waveguide (100) by injection laser diode bars (104). A large number of gain media channels (101) are separated into a repeating space across the pump waveguide, termed herein a “pixel” (106). The TPMWGL is operated in the amplifier mode in that the optical signal to be amplified is input to the gain channel (102) and extracted or exits from the laser at the end of the gain channel (103). The gain media channels (101) are designed such that a single transverse mode is dominant, preferably having cross section dimensions on the order of 10 microns high by 10 microns wide.

The lasing media in the gain channels preferably has a sufficient absorption depth such the maximum output power per gain channel is sufficiently low to avoid all non-linear effects that lead to losses. For example, a gain channel output of desired length would be designed to absorb 20 Joules/second (J/s) and provide an output power of 10 J/second resulting in a 50% conversion efficiency. Note that this core power density is much less than those demonstrated in high power fiber lasers. This design criteria sets the thermal energy that must be removed from each gain channel at 10 J/s. Thermal management is important in these optical structures such that the pump waveguide is integrated into and sandwiched between two heat exchanger surfaces as illustrated in the following drawings.

The pump waveguide center (100) and integrated gain medium channels (101), illustrated in cross section of FIG. 2, are preferably formed employing optical integrated techniques similar to photo-lithographic techniques employed in semiconductor manufacturing. In FIG. 2, the fabrication process starts by depositing a pump waveguide cladding material (125) on one side of the laser matrix row heat exchanger (124). Additional layers (122) of optical materials are deposited on the original cladding layer. The index of refraction (index) of the additional layers (122) deposited on the initial cladding layer increases in steps to match that of the pump waveguide center (100) for the purpose of forming a graded index planar pump waveguide. Note that the outside cladding layer (125) may not be required, depending upon the thickness and index of the multiple layers which in themselves form a cladding. This structure serves to confine the optical pump energy (105) in the center of the pump waveguide where the gain media channels (101) are located. Note that the pump is symmetrical in that the layers on top of the pump waveguide center (100) are identical to those below. The assembly is capped by the top heat exchanger conductor (124) and the entire pump waveguide center (100), gradient layers (122), and cladding layers (125) are sandwiched between two heat exchanger surfaces (124).

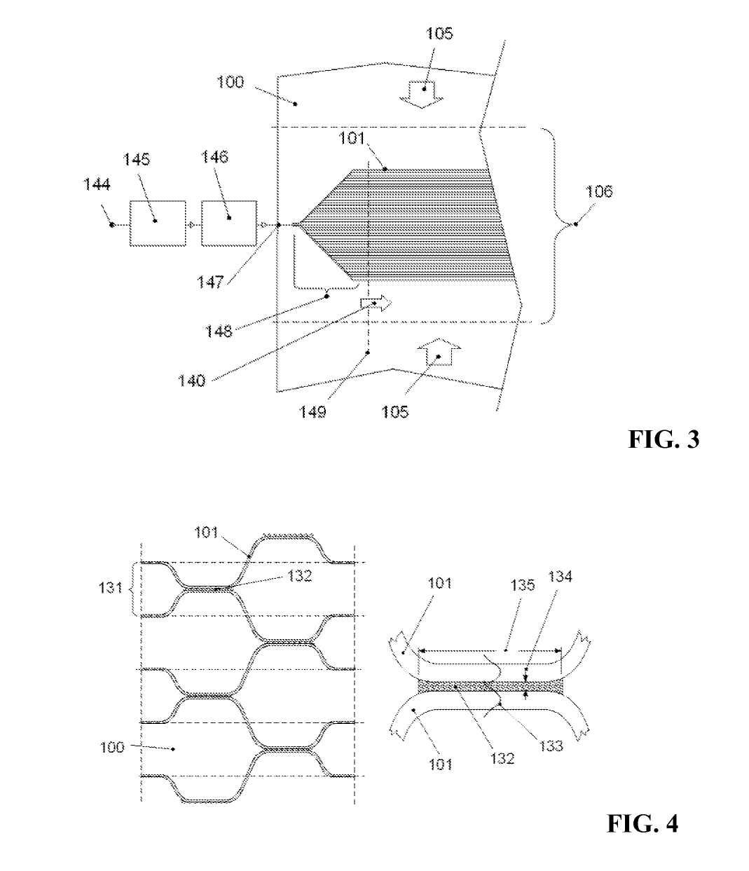

The large number of parallel gain channels (101) within a pixel grouping (106) located within the pump waveguide (100) must be coherent in phase in order to efficiently form a beam and combine the output energy of all the beams. In various situations, this may be accomplished by designing a input signal distribution system (148), illustrated in FIG. 3. The optical input or seed energy from a common source (144) is adjusted in phase (145) and amplitude (146) to provide the input (147) to the each pixel grouping (106). This optical energy is distributed among all gain channels (148) within the pixel in such a way that the phase of the optical energy in all the gain channels are coherent at the output front (149). Note that controlling the phase of each pixel in each row of the final matrix will allow the laser output matrix to replace deformable mirrors.

It may be necessary to further force coherence across the gain channels in one pixel as illustrated in FIG. 4. The path of parallel gain channels (101) with a nominal spacing (131) will be designed to interact with adjacent gain channels in a region in which propagation loss is provided (132), such as a saturable absorber material, in such a manner that the most efficient transport through the loss region occurs when the phase of the optical signal in both channels are synchronous. The length of the loss region (135) and the separation (134) of the interacting gain channels is designed to provide maximum transmission when the evanescent fields of the optical energy coincide (133). Note that this type of interaction is much more difficult to design in optical fiber systems. In addition, the fabrication processes may allow tuning and trimming with a UV laser before the top half of the pump wave guide is completed. Furthermore, Bragg mirrors can be implanted within the structure to define laser bandwidth if necessary using ion implantation techniques.

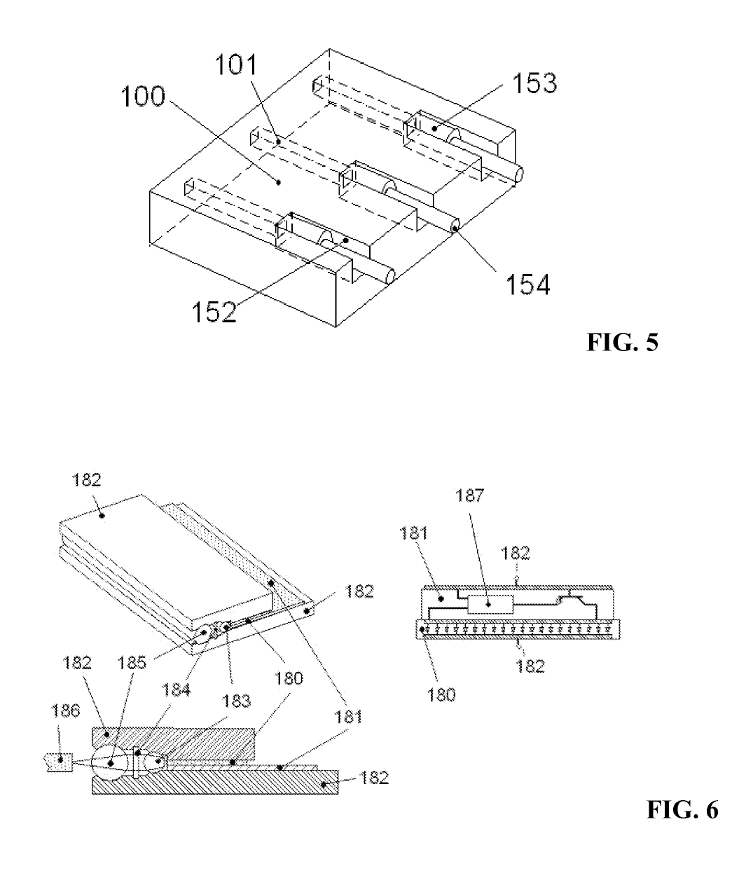

The output of the TPMWGL in the preferred embodiment requires extracting the optical waveguide energy from the single transverse mode beam in the square gain channel (101) using a micro-lens array or coupling the optical energy of each channel into a single mode optical fiber (154) as illustrated in FIG. 5. FIG. 5 illustrates one method for coupling the gain channel (101) output in which a channel (152) is etched into the pump waveguide (100) into which a Gradient Index Lens (GRIN) (153) is fused to the output optical fiber (154). The optical fiber can then be routed to an output plane where the output of the single mode (154) fiber is then collimated with a microlens.

FIG. 6 illustrates one configuration of the optical pump modules (222), the output of which is injected into the edges of the pump waveguide. The pump diode module (222) is an assembly that places the pump diode bar (104) in series with a semiconductor switch (181) that is used to turn off the bar diode in the event of a short failure. The semiconductor switch (181) and pump diode bar (104) are sandwiched between two metal electrodes (182) that each connect to a heat exchanger (124) body. Thus the pump diode current 227 flows through the top heat exchanger body (124), through the pump diode (104) and the series semiconductor switch (181), through the bottom heat exchanger body (124). Two other components are added to the pump diode assembly 222 (222). A rod collection lens (183) is inserted as illustrated to collect the rapidly expanding optical energy from the pump diode bar (104). A wavelength specific grating (184) is then inserted in the optical path to lock the diode output wavelength to a narrow band that is optimum for pump wavelength absorption in the gain channels (101). Finally, a second rod lens (185) is included in the pump diode assembly (222) to focus the pump optical energy on the input of the pump waveguide (186).

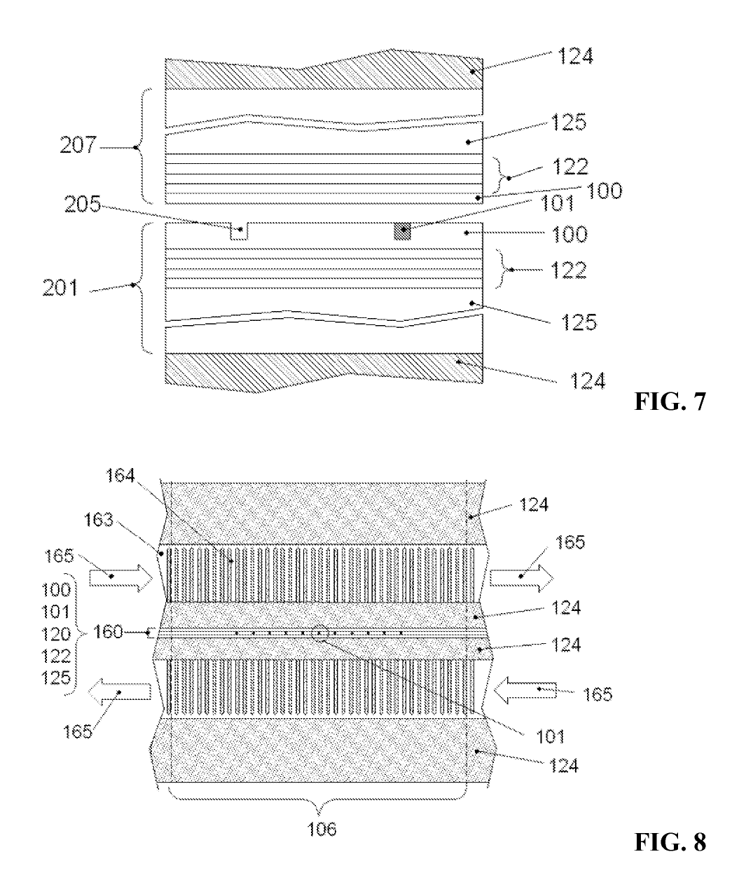

Fabrication of the pump waveguide structure is accomplished by depositing multiple layers of optical materials on one side of the heat exchanger (124) as illustrated in FIG. 7. The bulk cladding (125) is deposited on the heat exchanger (124) surface in accordance with standard optical design rules, followed by multiple layers of ever increasing index of refraction to form one half of a planar Gradient Index Lens (122) or GRIN lens. Then the major portion of the pump waveguide center (100) is deposited on the GRIN structure. Photo-lithographic processes are then used to form a mask to etch valleys (205) of the pattern of multiple gain channels, optical distribution network, and any other control configurations, including those illustrated in FIG. 1, FIG. 3, and FIG. 4, required into the pump waveguide center layer. Lasing media with appropriate absorption and gain characteristics, matched to the pump wavelength, is then deposited in the etched gain channel valleys (205) to form the gain channels (101).

At this point in the fabrication process where the initial deposition layers and gain channel have been completed (201), the system can be operated as a laser to add additional features like saturable absorber materials for phase coherence, Bragg mirror implants, adjust laser media volume or dimensions, and to trim and tune performance as required to certify the laser row quality before continuing. Note that the additional features can be accomplished using ion implants and UV laser ablation as well as other material modification methods.

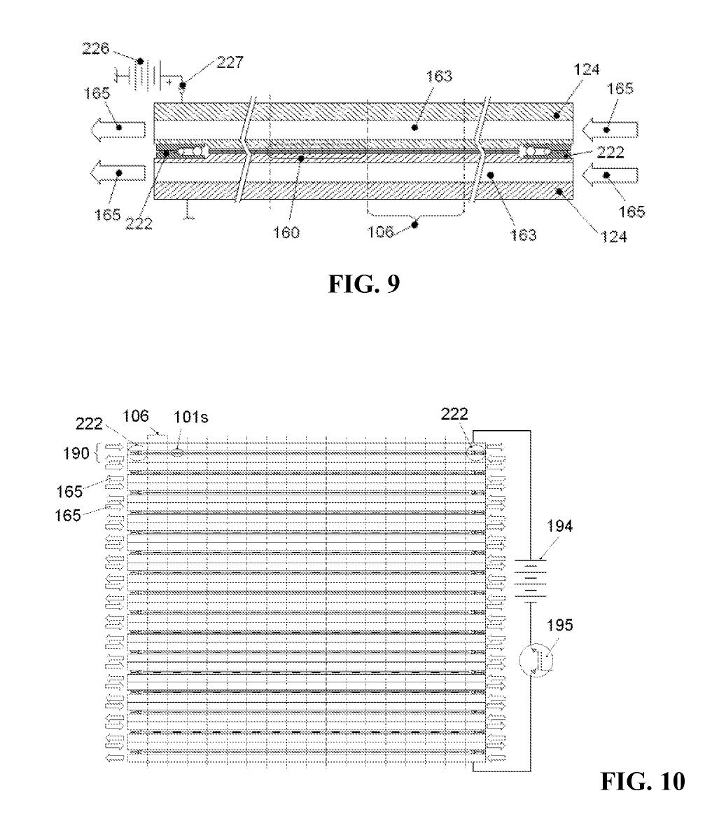

Once all the gain channels within each pixel with the laser row have been certified or extinguished, the final set of layers (207) can be deposited and the top heat exchanger body bonded to the stack to form a row of laser pixels as illustrated in FIG. 9. Note that the difference in expansion coefficients of the metallic heat exchanger body and the optical materials must be addressed by selection of appropriate materials at the interface between the heat exchanger body and the pump waveguide outer cladding.

FIG. 8 illustrates the detailed heat exchanger cross section for a single pixel (106) within a row of pixels that form a TPMWGL row to describe the thermal resistance and thermal energy extraction configuration. The pump waveguide assembly (160) in the vertical center of the figure is composed of the pump waveguide center, the gain channels (101), the GRIN pump waveguide core layers (122), and the pump waveguide outer cladding (125). The pump waveguide assembly (160) is sandwiched between the top and bottom heat exchanger bodies (124), in which two coolant channels (163) are located. The thermal resistance from the gain channels (101) to the near surface of the heat exchanger body (124) is very small due to the short distance and the thermal conductivities of the optical materials. Within the heat exchanger coolant channels (163), thermally conducting micro-pin structures (164) are constructed to increase the surface area exposed to the coolant flow (165) and to increase the turbulence of the coolant flow (165) to increase the effective thermal energy transfer from the heat exchanger body (124) coolant.

FIG. 9 illustrates the cross section of a complete TPMWGL row assembly which includes a number of pixels (106) each consisting of a large number of gain channels (101, 160). Thermal energy from the gain channels (101) in each pixel (106) in the TPMWGL row and thermal energy from the pump diode assemblies (122) is transferred to the coolant flowing (165) in the heat exchanger body (124) coolant channels (163). FIG. 9 also identifies the power source (226) connection to a single row and the current flowing (227) through the heat exchanger body (124) to power the pump diode assemblies (122).

FIG. 10 illustrates a cross section of a full TPMWGL system in which a number of single rows (190) of FIG. 9 are stacked and electrically connected vertically to form a matrix output configuration of laser pixels. The power system for the entire matrix consists of a single power source (226) and a semiconductor power switch (195). The heat exchanger in each row collects and transfers the thermal energy from the pump diode assemblies (222) and the gain channels (101) to the coolant flow (165). For continuous operation, the coolant flows of the entire laser would be in parallel. For pulsed operation, the coolant flows can be in series parallel combinations to allow the resultant thermal energy to be removed without increasing the temperature of the structure.

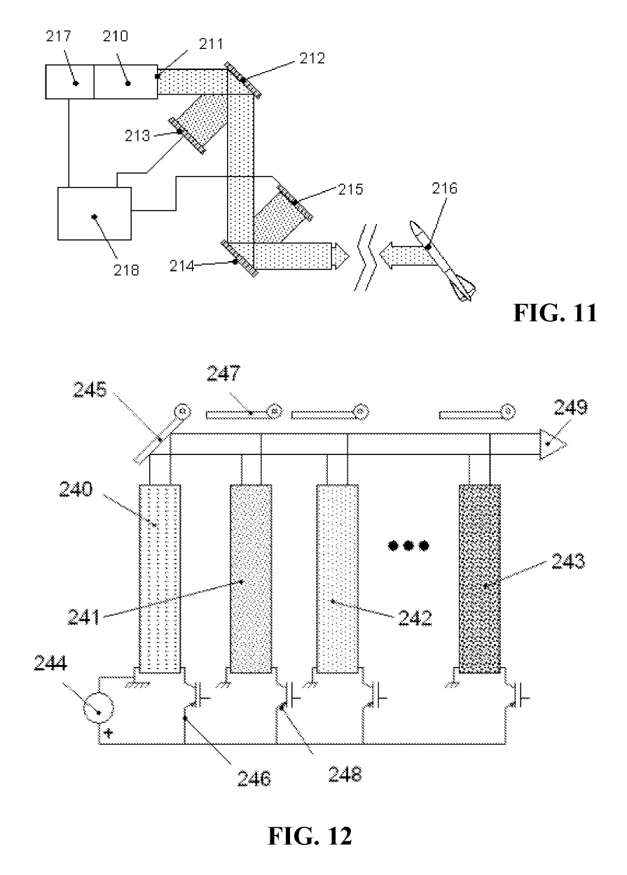

FIG. 11 is a system diagram illustrating how a TPMWGL system can be used to replace deformable mirrors that are used to introduce phase conjugation and increase the energy transferred to a target (216). A TPMWGL system (210) produces a pixelated matrix output set of beams in which the phase of each pixel (106) is controlled by controlling the phase of the input signal (147) to each pixel as in FIG. 3. The objective of a phase conjugation systems is to determine the phase distortion introduced by a beam traveling to a target (216) and then introduce a conjugate phase at the source such that the phase of all beams reach the target (216) in phase. This operation is normally performed using a deformable mirror, the surface of which is divided into pixels, each of which can be spatially adjusted to introduce a phase lead or lag on the input optical beams. One manner in which the phase control of each pixel in the TPMWGL output can be employed to replace deformable mirrors is as follows. First the phase of each TPMWGL output pixel is determined by imaging the face of a first or laser turning mirror (212) using a planar sensor (213). Using this data, phase control electronics (218) determine the output phase of each pixel from the output sensor (213) and adjust the input phase of each phase such that the all the pixels of the output beam front are in phase. The second step is to propagate a beam to the target (216) using the target turning mirror (214) and set up a target 216-in-the-loop configuration in which the thermal energy emitted by target 216 absorption is monitored using target mirror sensor (215). Then the phase control electronics are then used to adjust the phase of the pixel input signals to maximize thermal signature from target (216)

FIG. 12 is a multiple-laser system diagram in which multiple lasers are deployed at a site. Multiple lasers are preferred to allow maintenance and repair while maintaining operational capability. In addition, multiple lasers, each a with different wavelength, may be desirable to adjust for atmospheric propagation conditions. In any case, multiple lasers are required in an operational system where system operability at all times is critical.

In FIG. 12, TPMWGL laser No. 1 (240) is active and connected to the system power supply (244) with power switch no. 1 (246) while the output of laser no. 1 (241) is selected using output beam mirror No. 1 (245) to produce the system output 249. In the case that laser no. 1 (240) is off line or requiring maintenance, laser No. 2 (241) would be connected to the power system (244) with power switch No. 2 (248) and laser no. 2 beam selected with mirror no. 2 (247). This system design can connect any laser to the available power source and select the corresponding beam as the system output.

Unless otherwise stated, all technical and scientific terms used herein have the same meaning as commonly understood by one of ordinary skill in the art.

Although any methods and materials similar or equivalent to those described herein can also be used in the practice or testing of the present invention, a limited number of the exemplary methods and materials are described herein. It will be apparent to those skilled in the art that many more modifications are possible without departing from the inventive concepts herein.

All terms used herein should be interpreted in the broadest possible manner consistent with the context. In particular, the terms “comprises” and “comprising” should be interpreted as referring to elements, components, or steps in a non-exclusive manner, indicating that the referenced elements, components, or steps may be present, or utilized, or combined with other elements, components, or steps that are not expressly referenced. When a Markush group or other grouping is used herein, all individual members of the group and all combinations and subcombinations possible of the group are intended to be individually included.

All references cited herein are hereby incorporated by reference to the extent that there is no inconsistency with the disclosure of this specification. The present invention has been described with reference to certain preferred and alternative embodiments that are intended to be exemplary only and not limiting to the full scope of the present invention, as set forth in the appended claims.

The foregoing description presents one or more embodiments of various systems and methods. It should be noted that these and any other embodiments are exemplary and are intended to be illustrative of the invention rather than limiting. While the invention is widely applicable to various types of technologies and techniques, a skilled person will recognize that it is impossible to include all of the possible embodiments and contexts of the invention in this disclosure.

Furthermore, those skilled in the art will recognize that boundaries between the functionality of the above described acts, steps, and other operations are merely illustrative. The functionality of several operations may be combined into a single operation, and/or the functionality of a single operation may be distributed in additional operations. Moreover, alternative embodiments may include multiple instances of a particular operation or may eliminate one or more operations, and the order of operations may be altered in various other embodiments. Those of skill in the art may implement the described functionality in varying ways for each particular application, but such implementation decisions should not be interpreted as causing a departure from the spirit or scope of the present invention.

As used herein, the term “based on” is used to describe one or more factors that affect a determination. This term does not foreclose additional factors that may affect the determination. That is, a determination may be based solely on the named factors or based in part on those factors. Consider the phrase “determine A based on B.” While B may be a factor that affects the determination of A, such a phrase does not foreclose the determination of A from also being based on C. In other instances, A may be determined based solely on B.

Some benefits and advantages that may be provided by some embodiments have been described above. These benefits or advantages, and any elements or limitations that may cause them to occur or to become more pronounced are not to be construed as critical, required, or essential features of any or all of the claims. While the foregoing description refers to particular embodiments, it should be understood that the embodiments are illustrative and that the scope of the invention is not limited to these embodiments. Many variations, modifications, additions, and improvements to the embodiments described above are possible.

What is claimed is:

1. A laser, comprising:
a. a waveguide center;
b. a plurality of gain channels arranged longitudinally along the waveguide center, wherein the plurality of gain channels are separated into a plurality of gain channel groups across the waveguide center;
c. a plurality of laser diode bars arranged orthogonally to the plurality of gain channels.

2. The laser of claim 1, wherein each of the plurality of gain channels comprise a cross-sectional area small enough that a single transverse transmission mode is dominate in the gain channels.

3. The laser of claim 2, wherein each of the plurality of gain channels are about 10 microns high and about 10 microns wide.

4. The laser of claim 1, wherein the waveguide center comprises a top side and a bottom side, and wherein the laser further comprises a first heat exchanger surface attached at the top side of the waveguide center and a second heat exchanger surface attached at the bottom side of the waveguide center.

5. The laser of claim 4, further comprising a first cladding layer between the waveguide center and the first heat exchanger surface, and a second cladding layer between the waveguide center and the second heat exchanger surface.

6. The laser of claim 1, wherein each of the plurality of gain channels comprise a gain channel input and a gain channel output, and wherein the laser further comprises an input signal distribution system connected to the input of each of the plurality of gain channels, wherein the input signal distribution system comprises circuitry to control the phase and amplitude of seed energy directed to the input of each of the plurality of gain channels whereby optical energy emitted at the output of each of the plurality of gain channels is coherent with output energy emitted at the outputs of each of the other plurality of gain channels.

7. The laser of claim 1, further comprising a saturable absorber material between at least two of the plurality of gain channels.

8. The laser of claim 6, further comprising a micro-lens array connected to the output of each of the plurality of gain channels.

9. The laser of claim 6, further comprising a single mode optical fiber coupled to the output of each of the plurality of gain channels.

10. The laser of claim 9, further comprising a gradient index lens fused to the output of each of the plurality of gain channels thereby coupling each of the plurality of gain channels to the single mode optical fiber.

11. The laser of claim 6, further comprising a pump diode assembly, comprising:
a. a first rod collection lens;
b. a wavelength-specific grating in an optical path of the first rod collection lens; and
c. a second rod collection lens between the wavelength-specific grating and the gain channel inputs of the plurality of gain channels.

12. The laser of claim 6, further comprising:
a. a first turning mirror at the output of each of the plurality of gain channel groups to receive a laser beam from each of the plurality of gain channel groups;
b. a planar sensor directed toward the first turning mirror;
c. phase control electronics connected to the planar sensor to determine the output phase of each of the plurality of gain channel groups;
d. a second turning mirror positioned to receive the laser beam from the first turning mirror and direct the laser beam to a target;
wherein the phase control electronics adjust an input phase of the seed energy input to each of the gain channel groups in order that the laser beam from each of the gain channel groups is in phase.

13. A method for manufacturing a laser, comprising the method steps of:
a. forming a pump waveguide center;
b. etching into the pump waveguide center a plurality of gain media channels;
c. depositing a lasing media into the plurality of gain media channels;
d. depositing a first optical material layer over the pump waveguide center, wherein the first optical material layer comprises a first index of refraction; and
e. depositing a second optical material layer over the first optical material layer, wherein the second optical material layer comprises a second index of refraction that is greater than the first index of refraction.

14. The method of claim 13, comprising the step of depositing at least one additional optical layer, wherein each additional optical layer comprises an index of refraction that is greater than the second index of refraction and increases in steps from each previous additional optical layer such that a graded index planar pump waveguide is formed.

15. The method of claim 13, further comprising the step of depositing a pump waveguide cladding material onto the laser matrix row heat exchanger prior to applying the plurality of additional layers on the pump waveguide center.

16. The method of claim 13, further comprising the step of depositing a saturable absorber material between the plurality of gain channels.

17. The method of claim 13, further comprising the step of connecting a micro-lens array to an output of each of the plurality of gain channels.

18. The method of claim 13, further comprising the step of coupling a single mode optical fiber to an output of each of the plurality of gain channels.

19. The method of claim 18, further comprising the step of fusing a gradient index lens between the output of each of the plurality of gain channels and the single mode optical fiber.
